(19) United States
(12) Patent Application Publication
(10) Pub. No.: US 2009/0257300 A1
(43) Pub. Date: Oct. 15, 2009

(54) FUSE INFORMATION CONTROL DEVICE, SEMICONDUCTOR INTEGRATED CIRCUIT USING THE SAME, AND CONTROL METHOD THEREOF

(75) Inventors: Won Jun Choi, Ichon (KR); Jeong Woo Lee, Ichon-si (KR); Hyung Wook Moon, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 12/347,228

(22) Filed: Dec. 31, 2008

(30) Foreign Application Priority Data
Apr. 10, 2008 (KR) 10-2008-0033000

(51) Int. Cl. G11C 7/00; G11C 29/00

(52) U.S. Cl. 365/225.7; 365/196; 365/194; 365/200

(57) ABSTRACT

A fuse information control device having a delay circuit to delay an active signal, includes a fuse circuit that outputs fuse information in response to a fuse information control signal, and a fuse information control signal generating unit that generates the fuse information control signal in response to one of the active signal and internal delay signals of the delay circuit.

### CROSS-REFERENCES TO RELATED APPLICATION

The present application claims priority under 35 U.S.C. §119(a) to Korean patent application number 10-2008-0033000, filed on Apr. 10 2008, in the Korean Intellectual Property Office, which is incorporated by reference in its entirety as if set forth in full.

### BACKGROUND

1. Technical Field

The embodiments described herein relate to a semiconductor integrated circuit (IC) and, more particularly, to a fuse information control device, a semiconductor IC using the same, and a control method thereof.

2. Related Art

In general, a semiconductor IC includes a redundant memory cell that can replace a defective memory cell that was created during the manufacturing process thereof, and a circuit that performs a repair operation by controlling the redundant memory cell. The semiconductor IC includes a fuse circuit for storing fuse information using the replaced memory cell, wherein the fuse information is stored in the fuse circuit by selectively cutting a plurality of fuses provided in the fuse circuit. Then, if a read or write command and an address corresponding to the read or write command are input to the semiconductor IC, the fuse information stored in the fuse circuit is output according to a predetermined control signal, i.e. a fuse information control signal, so that a repair operation is performed by determining if a memory cell corresponding to the input address must be replaced.

FIG. 1 is a schematic circuit diagram of a conventional fuse information control device. In FIG. 1, the fuse information control device 10 generates a fuse information control signal ‘XFENP’ using an inverted active signal ‘ACTPB’ and delay signals ‘D1’ to ‘Dx’ having a plurality of delay time periods, each different from one another. In addition, the fuse information control device 10 includes a fuse circuit 12 that outputs fuse information according to the fuse information control signal ‘XFENP’. Furthermore, the fuse information control device 10 further includes the delay unit 11, a plurality of AND logic devices, and a plurality of NAND logic devices.

The active signal ‘ACTPB’ is a pulse signal generated according to an active command signal. A block activation signal ‘BSENP’ is used to activate a circuit block that determines if a memory cell must be replaced according to fuse information. The delay signals ‘D1’ to ‘Dx’ are branched from an interior of a delay unit 11 that generates the block activation signal ‘BSENP’ by delaying the active signal ‘ACTPB’.

FIG. 2 is a timing diagram demonstrating a conventional operation of a fuse information control device. In FIG. 2, the fuse information control device generates the fuse information control signal ‘XFENP’, which has a pulse width wider than that of the active signal ‘ACTPB’, by summing up all low level intervals of the inverted active signal ‘ACTPB’ and the delay signals ‘D1’ to ‘Dx’ using the AND logic devices and the NAND logic devices.

However, the fuse information control device has the following problems. First, the pulse width of the fuse information control signal ‘XFENP’ must be sufficient enough to ensure an operation margin of the circuit block that determines if the memory cell must be replaced. Since the fuse information control device generates the fuse information control signal ‘XFENP’ using the AND logic devices and the NAND logic devices, the number of the AND logic devices and the NAND logic devices is increased, and thus, a circuit size is increased in order to generate the fuse information control signal ‘XFENP’ having a sufficient pulse width. Accordingly, in order to minimize the overall circuit size, a circuit design must be performed such that the pulse width of the fuse information control signal ‘XFENP’ has a minimum value in order to satisfying a design standard. Since the pulse width of the fuse information control signal ‘XFENP’ is insufficient, the operation margin of the circuit block is not sufficiently ensured, and thus an error may occur during the repair operation.

In addition, since signal delay basically occurs in the AND logic devices and the NAND logic devices, activation of the fuse information control signal ‘XFENP’ can be delayed, as illustrated in FIG. 2.

Finally, since the fuse information control signal ‘XFENP’ is generated by summation of a plurality signals, i.e. the active signal ‘ACTPB’ and the delay signals ‘D1’ to ‘Dx’, many signal lines are required. Thus, noise may be generated in the fuse information control signal ‘XFENP’ when any one of process/voltage/temperature (PVT) variations occur.

### SUMMARY

A fuse information control device capable of reducing a circuit size for generating a fuse information control signal and activating the fuse information control signal, a semiconductor IC using the same, and a control method thereof are described herein.

In one aspect, A fuse information control device having a delay circuit to delay an active signal, the fuse information control includes a fuse circuit that outputs fuse information in response to a fuse information control signal, and a fuse information control signal generating unit that generates the fuse information control signal in response to one of the active signal and internal delay signals of the delay circuit.

In another aspect, a semiconductor integrated circuit includes a sense amplifier controller that generates a plurality of driving signals for driving a sense amplifier by delaying an active signal by a plurality of time periods, each different from one another, a fuse circuit that outputs fuse information in response to a fuse information control signal, and a fuse information control signal generating unit that generates the fuse information control signal in response to one of the active signal and internal delay signals of the sense amplifier controller.

In another aspect, a fuse information control method of a semiconductor integrated circuit including a delay circuit that delays an active signal and a fuse circuit that outputs fuse information in response to a fuse information control signal, the fuse information control method includes activating the fuse information control signal in response to the active signal, and deactivating the fuse information control signal in response to one of internal delay signals of the delay circuit.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic circuit diagram of a conventional fuse information control device;

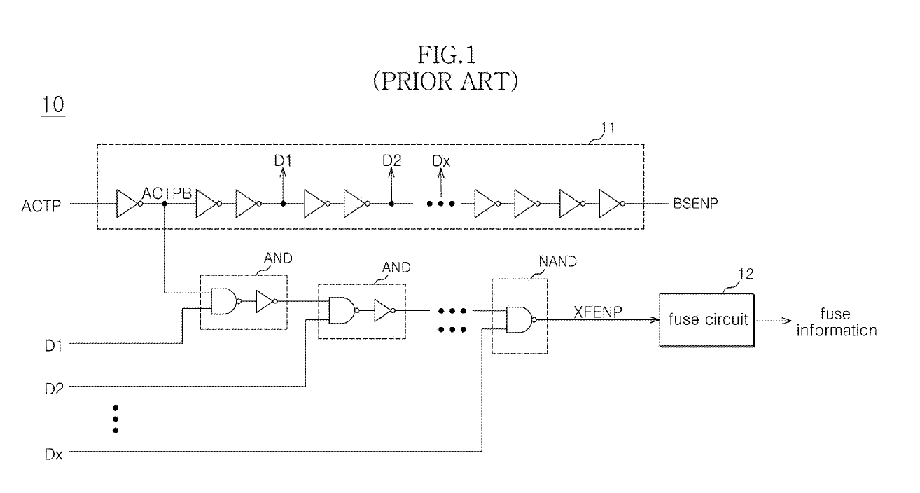

FIG. 2 is a timing diagram demonstrating a conventional operation of a fuse information control device;

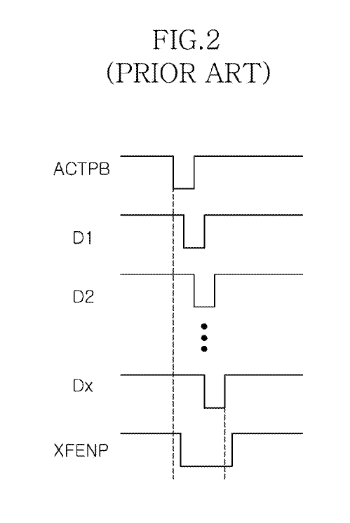

FIG. 3 is a schematic block diagram of an exemplary fuse information control device according to one embodiment;

FIG. 4 is a schematic circuit diagram of an exemplary fuse information control signal generating unit that can be included in the device of FIG. 3 according to one embodiment; and

FIG. 5 is a timing diagram demonstrating an exemplary operation of a fuse information control device according to one embodiment.

### DETAILED DESCRIPTION

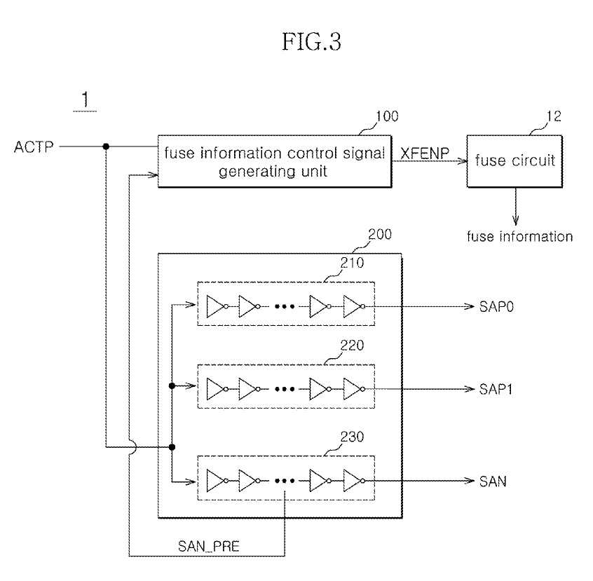

FIG. 3 is a schematic block diagram of an exemplary fuse information control device according to one embodiment. In FIG. 3, a fuse information control device 1 can be configured to include a fuse circuit 12, a fuse information control signal generating unit 100, and a sense amplifier controller 200. The fuse circuit 12 can output fuse information in response to a fuse information control signal ‘XFENP’. The fuse information control signal generating unit 100 can generate the fuse information control signal ‘XFENP’ using a pulse-type active signal ‘ACTP’ and a preliminary sense amplifier driving signal ‘SAN_PRE’.

The sense amplifier controller 200 can generate first to third driving signals ‘SAP0’, ‘SAP1’, and ‘SAN’ by delaying the pulse-type active signal ‘ACTP’ by a plurality of time periods, each different from one another. The first driving signal ‘SAP0’ can be used to supply power voltage to a sense amplifier. For example, the first driving signal ‘SAP0’ can be used to supply power to the sense amplifier during an over-driving operation, the second driving signal ‘SAP1’ can be used to supply power to the sense amplifier after the over-driving operation, and the third driving signal ‘SAN’ can be used to supply ground power to the sense amplifier.

The sense amplifier controller 200 can be arranged to include first to third signal generating units 210, 220, and 230 for generating the first to third driving signals ‘SAP0’, ‘SAP1’, and ‘SAN’, respectively. In addition, the first, second, and third signal generating units 210, 220, and 230 can each include a plurality of delay elements, i.e., a plurality of inverters.

The preliminary sense amplifier driving signal ‘SAN_PRE’ can be selected from output signals of the delay elements of the third signal generating unit 230, and can be used to generate the third driving signal ‘SAN’, in which an output signal having a desired delay time period is selected as the preliminary sense amplifier driving signal ‘SAN_PRE’.

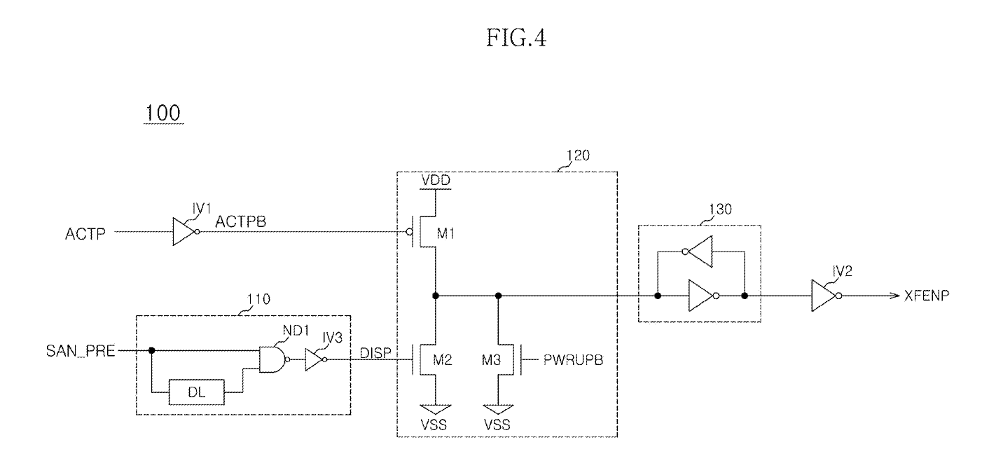

FIG. 4 is a schematic circuit diagram of an exemplary fuse information control signal generating unit of FIG. 3 according to one embodiment. In FIG. 4, the fuse information control signal generating unit 100 can be configured to include first and second inverters IV1 and IV2, a pulse generating unit 110, a signal shifting unit 120, and a latch unit 130.

The pulse generating unit 110 can generate a pulse-type deactivation signal ‘DISP’ for deactivating the fuse information control signal ‘XFENP’ if the preliminary sense amplifier driving signal ‘SAN_PRE’ is activated. The pulse generating unit 110 can be arranged to include an inversion delay element DL, a NAND gate ND1, and a third inverter IV3.

The signal shifting unit 120 can activate the fuse information control signal ‘XFENP’ if the inverted pulse-type active signal ‘ACTPB’ is generated, and can deactivate the fuse information control signal ‘XFENP’ if the pulse-type deactivation signal ‘DISP’ is generated. The signal shifting unit 120 can include first to third transistors M1 to M3, wherein the third transistor M3 can initialize the fuse information control signal ‘XFENP’ according to a power-up signal ‘PWRUPB’.

The latch unit 130 can maintain a level of the fuse information control signal ‘XFENP’ shifted by the inverted pulse-type active signal ‘ACTPB’ and deactivation signal ‘DISP’.

The first to third driving signals ‘SAP0’, ‘SAP1’, and ‘SAN’ output from the sense amplifier controller 200 (of FIG. 3) can be activated on the basis of the pulse-type active signal ‘ACTP’. In addition, as shown in FIGS. 3 and 4, the fuse information control signal ‘XFENP’ can also be activated on the basis of the inverted pulse-type active signal ‘ACTPB’. Thus, one preliminary signal of the first to third driving signals ‘SAP0’, ‘SAP1’, and ‘SAN’ can be used as a reference for deactivating the fuse information control signal ‘XFENP’. For example, the preliminary sense amplifier driving signal ‘SAN_PRE’, which is a preliminary signal of the third driving signal ‘SAN’, can be used to ensure the fuse information control signal ‘XFENP’ can have a proper activation interval.

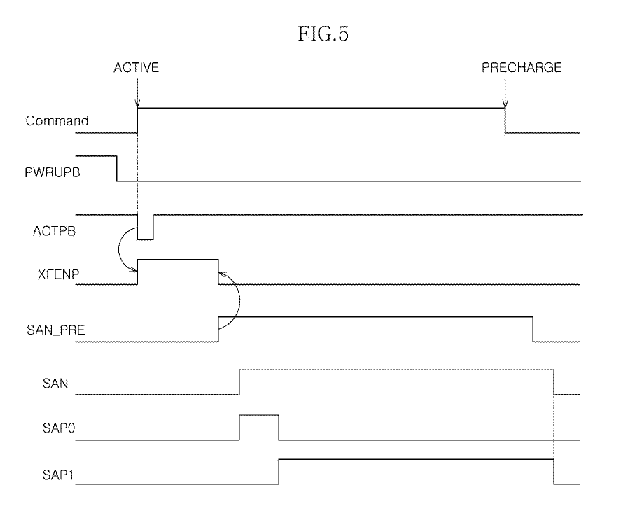

An exemplary operation of a fuse information control device 1 (of FIG. 3, for example) will be described with regard to FIG. 5 in which a timing diagram is demonstrated for an exemplary operation of a fuse information control device according to one embodiment.

As the semiconductor IC is powered ON and the power-up signal ‘PWRUPB’ is at a low level, the fuse information control signal ‘XFENP’ can be initialized to a low level. Then, if an active command, such as a read or write command, is input to the fuse information control device 1, a high pulse-type active signal ‘ACTP’ can be generated. The inverted pulse-type active signal ‘ACTPB’ can be generated by inverting the pulse-type active signal ‘ACTP’, as shown in FIG. 4. As the inverted pulse-type active signal ‘ACTPB’ is generated, the signal shifting unit 120 (of FIG. 4) can activate the fuse information control signal ‘XFENP’ to a high level.

Meanwhile, as the pulse-type active signal ‘ACTP’ is generated, the first to third signal generating units 210, 220, and 230 of the sense amplifier controller 200 (of FIG. 3) can activate the first to third driving signals ‘SAP0’, ‘SAP1’, and ‘SAN’ according to a predetermined timing, respectively. During generation of the third driving signal ‘SAN’, the preliminary sense amplifier driving signal ‘SAN_PRE’ can be input to the fuse information control signal generating unit 100 from the third signal generating unit 230. As the preliminary sense amplifier driving signal ‘SAN_PRE’ is activated, the signal shifting unit 120 (of FIG. 4) can allow the fuse information control signal ‘XFENP’ to be transitioned to a low level.

As descried above, the fuse information control signal ‘XFENP’ can be controlled to have a desired activation interval using the preliminary sense amplifier driving signal ‘SAN_PRE’ without using an additional signal delay circuit. In addition, the signal shifting unit 120 (of FIG. 4) can directly activate the fuse information control signal ‘XFENP’ in response to the inverted pulse-type active signal ‘ACTPB’ so that the fuse information control signal ‘XFENP’ can be activated quickly and efficiently.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A fuse information control device having a delay circuit to delay an active signal, the fuse information control device comprising:
a fuse circuit that outputs fuse information in response to a fuse information control signal; and
a fuse information control signal generating unit that generates the fuse information control signal in response to one of the active signal and internal delay signals of the delay circuit.

2. The fuse information control device of claim 1, wherein the delay circuit is included in a sense amplifier controller that generates at least one sense amplifier driving signal for controlling a sense amplifier by delaying the active signal.

3. The fuse information control device of claim 1, wherein the fuse information control signal generating unit activates the fuse information control signal in response to the active signal and deactivates the fuse information control signal in response to one of the internal delay signals.

4. The fuse information control device of claim 1, wherein the fuse information control signal generating unit includes:
a pulse generating unit that generates a pulse signal if one of the internal delay signals is activated; and
a signal shifting unit that activates the fuse information control signal in response to the active signal, and that deactivates the fuse information control signal in response to the pulse signal.

5. The fuse information control device of claim 4, wherein the fuse information control signal generating unit further includes a circuit that initializes the fuse information control signal in response to a power-up signal.

6. A semiconductor integrated circuit, comprising:
a sense amplifier controller that generates a plurality of driving signals for driving a sense amplifier by delaying an active signal by a plurality of time periods, each different from one another;
a fuse circuit that outputs fuse information in response to a fuse information control signal; and
a fuse information control signal generating unit that generates the fuse information control signal in response to one of the active signal and internal delay signals of the sense amplifier controller.

7. The semiconductor integrated circuit of claim 6, wherein the internal delay signals are generated by branching output of a plurality of delay elements for generating the driving signals.

8. The semiconductor integrated circuit of claim 6, wherein the fuse information control signal generating unit activates the fuse information control signal in response to the active signal, and deactivates the fuse information control signal in response to one of the internal delay signals.

9. The semiconductor integrated circuit of claim 6, wherein the fuse information control signal generating unit includes:
a pulse generating unit that generates a pulse signal if one of the internal delay signals is activated; and
a signal shifting unit that activates the fuse information control signal in response to the active signal, and that deactivates the fuse information control signal in response to the pulse signal.

10. The semiconductor integrated circuit of claim 9, wherein the fuse information control signal generating unit further includes a circuit that initializes the fuse information control signal in response to a power-up signal.

11. A fuse information control method of a semiconductor integrated circuit including a delay circuit that delays an active signal and a fuse circuit that outputs fuse information in response to a fuse information control signal, the fuse information control method comprising:
activating the fuse information control signal in response to the active signal; and
deactivating the fuse information control signal in response to one of internal delay signals of the delay circuit.

12. The fuse information control method of claim 11, wherein the internal delay signals include internal delay signals of the delay circuit provided in order to generate a sense amplifier driving signal by delaying the active signal by a plurality of time periods, each different from one another.
